(19) United States
(12) Patent Application Publication
(10) Pub. No.: US 2025/0098372 A1
(43) Pub. Date: Mar. 20, 2025

(54) LIGHT EMITTING DEVICE AND METHOD FOR MANUFACTURING LIGHT EMITTING DEVICE

(71) Applicant: TOYODA GOSEI CO., LTD., Kiyosu-shi (JP)

(72) Inventors: Koichi MIZUTANI, Kiyosu-shi (JP); Hideki OMOYA, Kiyosu-shi (JP); Shinichi MATSUI, Kiyosu-shi (JP); Hiroaki MAKINO, Kiyosu-shi (JP)

(21) Appl. No.: 18/790,756

(22) Filed: Jul. 31, 2024

(30) Foreign Application Priority Data
Sep. 15, 2023 (JP) 2023-150035

(51) Int. Cl. H01L 33/42; H01L 33/00; H01L 33/32; H01L 33/46

(52) U.S. Cl. CPC H10H 20/833; H10H 20/0137; H10H 20/825; H10H 20/841; H10H 20/032

(57) ABSTRACT

The present disclosure provides a light emitting device in which the ultraviolet reflectance can be improved while the p-side electrode can form ohmic contact with the p-type layer. A flip-chip type ultraviolet light emitting device includes an n-type layer, an active layer, a p-type layer, a p-side electrode formed on the p-type layer, including a layer in contact with the p-type layer and made of Ru, Rh, or an alloy containing those metals as a main component, and having a thickness that transmits ultraviolet light with an emission wavelength, an insulating DBR layer formed on and in contact with a part of the p-side electrode, and reflecting ultraviolet light with an emission wavelength, a second p-side electrode being electrically connected with the p-side electrode through a hole formed in a region on the p-side electrode of the DBR layer.

### CROSS-REFERENCE

This application claims priority to Japanese patent application no. 2023-150035 filed on Sep. 15, 2023, the contents of which are fully incorporated herein by reference.

### BACKGROUND OF THE INVENTION

### Technical Field

The present disclosure relates to a light emitting device and a method for manufacturing the light emitting device.

### Background Art

The wavelength of ultraviolet light emitted from a solid-state light emitting device made of group III nitride semiconductor corresponds to a wavelength band in a range of approximately 210 nm to 400 nm. UVC (ultraviolet C having a wavelength of 100 nm to 280 nm) is known to efficiently sterilize or disinfect, and its use for sterilizing and disinfecting water or air has been attracting attention. Therefore, the demand is increasing for a group III nitride semiconductor light emitting device that emits ultraviolet light with an emission wavelength of UVC, and research and developments for improving the light extraction efficiency have been actively conducted.

JP-A-2022-30948 discloses an UVC light emitting device made of group III nitride semiconductor having a structure in which a p-side electrode includes a Rh layer in contact with a p-type semiconductor layer and having a thickness of 10 nm or less, and an Al layer in contact with the Rh layer and having a thickness of 20 nm or more. With such a structure, the reflectance can be increased as well as the contact resistance is reduced. Moreover, the Rh layer and the Al layer are mixed by annealing the p-side electrode. As a result, the reflectance is increased as compared with a case in which only the Rh layer is used, by combining the Rh layer and the Al layer.

JP-A-2023-34227 discloses an UVC light emitting device made of group III nitride semiconductor having a structure in which a p-side electrode includes a transparent electrode, a p-electrode, and a p-side junction electrode. The transparent electrode is provided on and in contact with a p-type semiconductor layer, and made of transparent conductive material such as ITO or IZO. The p-electrode is provided on and in contact with the transparent electrode, and made of Ni/Au or Ni/Al. Here, A/B means a layered structure in which B was formed after A was formed. Hereinafter, the same shall apply in this specification. The p-side junction electrode is provided on and in contact with the p-electrode, and made of Au or other materials.

JP-A-2023-34227 also discloses that a reflective insulating film made of SiO₂, SiN, SiO₂/Al/SiO₂, DBR layer (DBR: Distributed Bragg Reflector) or other material is formed over the transparent electrode and the p-type layer, and the reflective insulating film reflects light emitted from the active layer constituting the semiconductor layer to improve light extraction.

JP-A-2015-220456 discloses a red, green and blue light emitting diode made of group III nitride semiconductor having a structure which includes a conductive layer formed on and in contact with a p-type semiconductor layer and having high transmittance at an emission wavelengths, a conductive reflective layer formed on and in contact with the conductive layer, an insulating layer formed on and in contact with the reflective layer, and an electrode formed on the insulating layer so as to penetrate the insulating layer.

The conductive layer is made of one or more of transparent oxide-based material having high transmittance at an emission wavelength emission wavelength, such as ITO, TO, IZO, IZTO, IAZO, IGZO, IGTO, AZO, ATO, GZO, IrOx, RuOx, RuOx/ITO, Ni, Ag, Ni/IrOx/Au and Ni/IrOx/Au/ITO. The reflective layer may include a reflective metal having a high electrical conductivity, for example, at least one of Ni, Pd, Ru, Mg, Zn, Hf, Ag, Al, Au, Pt, Cu or Rh, or an alloy thereof. The insulating layer may be formed of at least one of Al₂O₃, SiO₂, Si₃N₄, TiO₂ or AlN, and may include a DBR.

### SUMMARY OF THE INVENTION

At present, a material capable of forming ohmic contact with p-AlGaN or p-GaN has a low reflectance for light in an ultraviolet region (especially UVC). Although Al has a high reflectance for light in the ultraviolet region, Al cannot form ohmic contact with p-AlGaN or p-GaN. Therefore, it had been desired that the ultraviolet reflectance is improved while the p-side electrode can form ohmic contact with the p-type layer.

In JP-A-2022-30948, there was a possibility that the p-type layer is in contact with Al due to dispersion of Al, thereby increasing the contact resistance. In JP-A-2023-34227, there was a room for improvement in terms of ohmic contact and reflectance. JP-A-2015-220456 does not relate to an UVC light emitting device, and there was a room for consideration in order to improve the ohmic contact and increase the ultraviolet reflectance in the ultraviolet region.

The present disclosure has been made in view of such a background, and an object thereof is to provide a light emitting device and a method for manufacturing the light emitting device in which the p-side electrode can form ohmic contact with the p-type layer and the ultraviolet reflectance can be increased.

One aspect of the present disclosure is a flip-chip type ultraviolet light emitting device including:
an n-type layer made of n-type group III nitride semiconductor;
an active layer formed on the n-type layer and made of group III nitride semiconductor;
a p-type layer formed on the active layer and made of p-type group III nitride semiconductor;
a p-side electrode formed on the p-type layer, including a layer made of Ru, Rh, or an alloy containing those metals as a main component and formed in contact with the p-type layer, and having a thickness that transmits ultraviolet light with an emission wavelength;
an insulating DBR layer formed on and in contact with a part of the p-side electrode, and reflecting ultraviolet light with an emission wavelength; and
a second p-side electrode being electrically connected with the p-side electrode through a hole formed in a region on the p-side electrode of the DBR layer.

As used herein, unless otherwise specified, the term “on” broadly encompasses both “directly on” and “indirectly on”.

The other aspect of the present disclosure is a method for manufacturing a flip-chip type ultraviolet light emitting device, the method including:
forming an n-type layer made of n-type group III nitride semiconductor;
forming an active layer made of group III nitride semiconductor on the n-type layer;
forming a p-type layer made of p-type group III nitride semiconductor on the active layer;
forming a p-side electrode on the p-type layer, the p-side electrode including a layer made of Ru, Rh, or an alloy containing those metals as a main component and formed in contact with the p-type layer, and having a thickness that transmits ultraviolet light with an emission wavelength;
forming an insulating DBR layer on and in contact with a part of the p-side electrode, the DBR layer reflecting ultraviolet light with an emission wavelength; and
forming a second p-side electrode to be electrically connected with the p-side electrode through a hole formed in a region on the p-side electrode of the DBR layer.

According to the above aspects of the present disclosure, the p-side electrode formed in contact with the p-type layer includes a layer made of Ru, Rh, or an alloy containing those metals as a main component. The layer is in contact with the p-type layer, thereby forming ohmic contact between the p-type layer and the p-side electrode in an ultraviolet ray region. In addition, an insulating DBR layer reflecting ultraviolet light with an emission wavelength is formed on and in contact with the p-side electrode, thereby forming a thin p-side electrode. A thin p-side electrode prevents ultraviolet light emitted from the active layer from being absorbed by the p-side electrode and allows the ultraviolet light to pass through the p-side electrode and reach the DBR layer. As a result, the DBR layer can efficiently reflect the ultraviolet light, thereby increasing the light extraction efficiency. Moreover, the DBR layer has insulating properties. Therefore, even if the p-side electrode is thin and the DBR layer is partially in contact with the top surface of the p-type layer, a problem such as deterioration of contact resistance does not occur.

According to the above aspects of the present disclosure, there is provided a light emitting device in which the ultraviolet reflectance can be increased while the p-side electrode can form ohmic contact with the p-type layer, and a method for manufacturing the light emitting device.

### BRIEF DESCRIPTION OF THE DRAWINGS

FIG. 1 is a cross-sectional view illustrating a configuration of a light emitting device according to a first embodiment, the cross-sectional view taken in a direction perpendicular to a main surface of a substrate;

FIG. 2 is a plan view illustrating the configuration of the light emitting device according to the first embodiment, the plan view being viewed from a top surface of the light emitting device;

FIG. 3 shows a step of manufacturing the light emitting device according to the first embodiment;

FIG. 4 shows a step of manufacturing the light emitting device according to the first embodiment;

FIG. 5 shows a step of manufacturing the light emitting device according to the first embodiment;

FIG. 6 shows a step of manufacturing the light emitting device according to the first embodiment;

FIG. 7 shows a step of manufacturing the light emitting device according to the first embodiment;

FIG. 8 shows a step of manufacturing the light emitting device according to the first embodiment;

FIG. 9 shows a step of manufacturing the light emitting device according to the first embodiment; and

FIG. 10 is a graph showing wavelength dependence of reflectance of DBR and Al.

### DETAILED DESCRIPTION OF PREFERRED EMBODIMENTS

A flip-chip type ultraviolet light emitting device includes an n-type layer made of n-type group III nitride semiconductor, an active layer formed on the n-type layer and made of group III nitride semiconductor, a p-type layer formed on the active layer and made of p-type group III nitride semiconductor, a p-side electrode formed on the p-type layer, including a layer made of Ru, Rh, or an alloy containing those metals as a main component and in contact with the p-type layer, and having a thickness so as to transmit ultraviolet light with an emission wavelength, and an insulating DBR layer formed on and in contact with a part of the p-side electrode and reflecting ultraviolet light with an emission wavelength, a second p-side electrode being electrically connected with the p-side electrode through a hole formed in a region on the p-side electrode of the DBR layer.

In the light emitting device, the DBR layer may be formed on and in contact with a part of the p-side electrode and in contact with at least one side surface of the n-type layer, the active layer, and the p-type layer. The DBR layer has insulating properties. Therefore, the DBR layer can be formed in contact with at least one side surface of the n-type layer, the active layer, and the p-type layer as well as on the p-side electrode. As a result, an area capable of reflecting ultraviolet light can be enlarged, thereby improving the light extraction efficiency. Here, a side surface of the layers constituting the semiconductor layer (the n-type layer, the active layer, and the p-type layer) includes an outer peripheral surface of the semiconductor layer, and when a hole or a trench is formed, at least a part of an inner peripheral surface of the hole or a side surface of the trench.

The ultraviolet light emitting device may have an emission wavelength of 200 nm to 280 nm. Within this emission wavelength range, when the DBR layer is applied as a reflective layer, the reflectance can be certainly increased compared to when Al is applied as a reflective layer. Thus, the light extraction efficiency can be increased.

The DBR layer may also contain HfO₂. This can achieve high reflectance within an emission wavelength range of 200 nm to 280 nm. The DBR layer may contain a material other than HfO₂.

The thickness of the p-side electrode may be 1 nm to 50 nm. By setting the thickness of the p-side electrode to 1 nm to 50 nm, the reflectance of ultraviolet ray can be increased. Moreover, when the thickness of the p-side electrode is 1 nm to 50 nm, even if the DBR layer is partially in contact with the top surface of the p-type layer, a problem such as deterioration of contact resistance does not occur because the DBR layer has insulating properties.

The p-type layer includes a p-type contact layer in contact with the p-side electrode and made of GaN. The thickness of the p-type contact layer is preferably 1 nm to 50 nm.

The p-type layer includes a p-type contact layer in contact with the p-side electrode and made of AlGaN having an Al composition of 50% or less. The thickness of the p-type contact layer is preferably 20 nm or less.

The above-described light emitting device can be manufactured as follows. That is, a method for manufacturing a flip-chip type ultraviolet light emitting device includes an n-type layer forming step of forming an n-type layer made of n-type group III nitride semiconductor, an active layer forming step of forming an active layer made of group III nitride semiconductor on the n-type layer, a p-type layer forming step of forming a p-type layer made of p-type group III nitride semiconductor on the active layer, a p-side electrode forming step of forming a p-side electrode on the p-type layer, including a layer made of Ru, Rh, or an alloy containing those metals as a main component and formed in contact with the p-type layer, and having a thickness that transmits ultraviolet light with an emission wavelength, a DBR layer forming step of forming an insulating DBR layer on and in contact with a part of the p-side electrode, and reflecting ultraviolet light with an emission wavelength, and a second p-side electrode forming step of forming a second p-side electrode so as to be electrically connected with the p-side electrode through a hole formed in a region on the p-side electrode of the DBR layer.

### First Embodiment

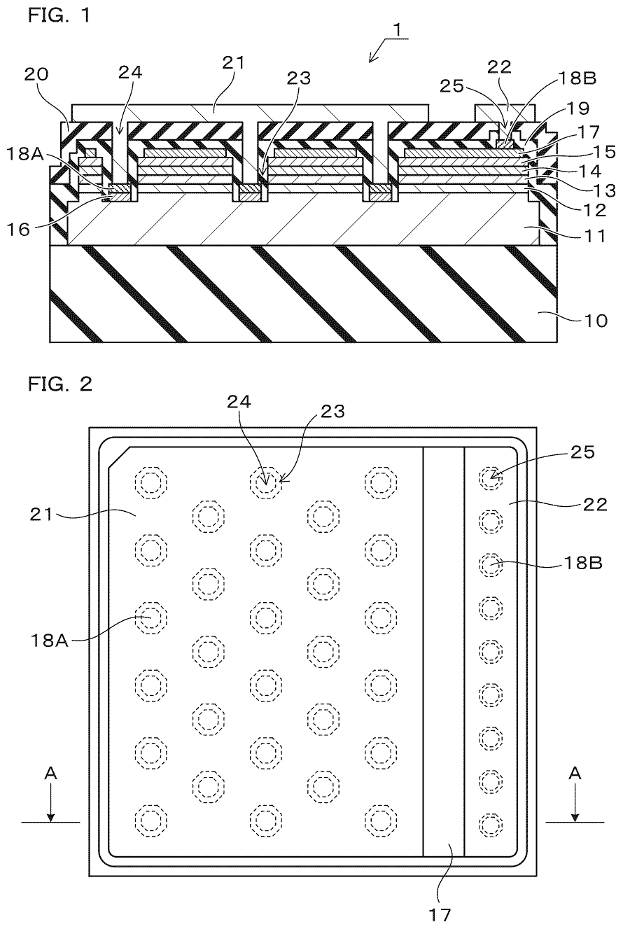

FIG. 1 is a cross-sectional view illustrating a configuration of a light emitting device according to a first embodiment, the cross-sectional view taken in a direction perpendicular to a main surface of a substrate. FIG. 2 is a view illustrating a planar pattern of the light emitting device 1 according to the first embodiment. The cross section of FIG. 1 corresponds to a cross section taken along line A-A in FIG. 2.

As shown in FIG. 1, the light emitting device 1 according to the first embodiment includes a substrate 10, an n-type layer 11, an active layer 12, an electron blocking layer 13, a composition gradient layer 14, a p-type contact layer 15, an n-side electrode 16, a p-side electrode 17, an etching stop layer 18, a DBR (Distributed Bragg Reflector) layer 19, a protective layer 20, an n-side pad electrode 21, and a p-side pad electrode 22. Hereinafter, a deposited structure from the n-type layer 11 to the p-type contact layer 15 is referred to as a semiconductor layer in some cases.

The light emitting device 1 according to the first embodiment is of a flip-chip type which extracts light from a rear surface of the substrate 10 (surface opposite to the n-type layer 11). The emission wavelength of the light emitting device 1 is a given wavelength in a rage from 210 nm to 280 nm, which is in the UVC band (100 nm to 280 nm).

### 1. Configuration of Light Emitting Device

The configuration of each layer of the light emitting device 1 according to the first embodiment will be described in detail.

The substrate 10 is a sapphire substrate having a c-plane main surface. The plane orientation of the main surface of the sapphire substrate may be a-plane. The substrate may also have an off-angle of 0.1 degrees to 2 degrees in the m-axis direction. Light is extracted mainly from a rear surface of this substrate 10 (surface opposite to the n-type layer 11). An anti-reflective film may be provided on the rear surface of the substrate 10 to improve the light extraction efficiency. Unevenness may be formed on the surface of the substrate 10 to improve the light extraction efficiency. An AlN substrate or an AlN template substrate having an AlN layer formed on the sapphire substrate may be used as the substrate 10.

The thickness of the substrate 10 is, for example, 1000 μm or less, preferably, 400 μm to 700 μm. This can suppress the light extraction from the side surface of the substrate 10, and improve the axial light intensity.

The substrate 10 may be removed by laser lift-off. An anti-reflective film may be formed on the rear surface of the substrate 10 to improve the light extraction efficiency.

The n-type layer 11 is disposed on the substrate 10. The n-type layer 11 is made of n-AlGaN. The Al composition (molar ratio of Al to the total of group III metals) is, for example, 60% to 90%. The n-type impurity is Si, and the Si concentration is, for example, 1×10¹⁸ cm⁻³ to 5×10¹⁹ cm⁻³. The thickness of the n-type layer 11 is, for example, 0.5 μm to 5 μm. The C concentration of the n-type layer 11 is 1×10¹⁵ cm⁻³ to 1×10¹⁹ cm⁻³. The n-type layer 11 may have a plurality of layers. For example, the n-type layer 11 may be a superlattice layer formed by alternately depositing AlGaN with different Al compositions. An AlN base layer may be formed between the substrate 10 and the n-type layer 11. Any material other than Si may be used as the n-type impurity.

The active layer 12 is disposed on the n-type layer 11. The active layer 12 has a single quantum well structure in which a barrier layer, a well layer, and a barrier layer are deposited in this order on the n-type layer 11. The active layer 12 may have a multiple quantum well structure. In this case, the number of repetitions is, for example, 2 to 10.

The well layer is made of AlGaN, and the Al composition is set according to a desired emission wavelength. The Si concentration of the well layer is, for example, 1×10¹⁸ cm⁻³ or may be undoped. The thickness of the well layer is, for example, 0.5 nm to 5 nm.

The barrier layer is made of AlGaN having an Al composition higher than the Al composition of the well layer. The Al composition of the barrier layer is, for example, 50% to 100%. The Si concentration of the barrier layer is, for example, 2×10¹⁹ cm⁻³ or less or may be undoped. The thickness of the barrier layer is, for example, 3 nm to 30 nm. The barrier layer may be made of AlGaInN having a band gap energy larger than the band gap energy of the well layer. The thickness of the layer in contact with the electron blocking layer 13 of the barrier layers is preferably 0.5 nm to 10 nm.

An electron hole blocking layer may be formed between the n-type layer 11 and the active layer 12. This can suppress the electron holes injected from the p-side electrode 17 from passing through the active layer 12 and dispersing into the n-type layer 11. The electron hole blocking layer is made of AlGaN or AlN having an Al composition higher than the Al composition of the barrier layer of the active layer 12. The thickness of the electron hole blocking layer is, for example, one molecular layer to 2 nm. In the case of AlN, the thickness of one molecular layer is about 0.26 nm.

The electron blocking layer 13 is disposed on the active layer 12. The electron blocking layer 13 has a two-layer structure in which a first electron blocking layer and a second electron blocking layer are sequentially deposited on the active layer 12 side. The electron blocking layer 13 suppresses the electrons injected from the n-side electrode 16 from passing through the active layer 12 and dispersing into the composition gradient layer 14.

The electron blocking layer 13 may not necessarily have a two-layer structure, and may have only the first electron blocking layer.

The first electron blocking layer is made of AlGaN or AlN having an Al composition higher than the Al composition of the barrier layer of the active layer 12. The Al composition of the first electron blocking layer is, for example, 90% to 100%. The first electron blocking layer may be doped with a p-type impurity or may be undoped. The p-type impurity is, for example, Mg. In the case of doping with Mg, the Mg concentration is, for example, 3×10²⁰ cm⁻³ or less. The thickness of the first electron blocking layer is, for example, 1 nm to 10 nm.

The second electron blocking layer is made of AlGaN having an Al composition lower than the Al composition of the first electron blocking layer. The Al composition of the second electron blocking layer is, for example, 80% to 99%. By forming the second electron blocking layer, the difference in Al composition from the composition gradient layer 14 is adjusted. The contact resistance is high in the case of only the first electron blocking layer made of AlN. When the thickness of the first electron blocking layer is reduced to lower the contact resistance, the electron blocking performance is deteriorated. Thus, the second electron blocking layer is formed to achieve both low contact resistance and high electron blocking performance. The second electron blocking layer may be doped with a p-type impurity or may be undoped. In the case of doping with Mg, the Mg concentration of the second electron blocking layer is, for example, 3×10²⁰ cm⁻³ or less. The thickness of the second electron blocking layer is, for example, 1 nm to 10 nm.

The composition gradient layer 14 is disposed on the electron blocking layer 13. The composition gradient layer 14 has a two-layer structure in which a first composition gradient layer and a second composition gradient layer are deposited in this order on the electron blocking layer 13.

The composition gradient layer 14 obtains p-type conduction by polarization doping. That is, the composition gradient layer 14 is a layer in which the Al composition varies in a thickness direction thereof, and the Al composition is set so as to be reduced with distance from the electron blocking layer 13. In the case of AlGaN having a high Al composition, the electron hole concentration was difficult to increase by doping with Mg. However, the electron hole concentration can be increased by polarization doping, thereby increasing the efficiency of electron hole injection into the active layer 12. The composition gradient layer 14 is not doped with Mg in the polarization doping, thereby improving the crystallinity.

When the Al composition of the composition gradient layer 14 is set as described above, polarization continuously occurs due to crystal deformation in a thickness direction of the composition gradient layer 14. Electron holes are generated in the composition gradient layer 14 to cancel the fixed charge caused by this polarization. The generated electron holes are distributed in the composition gradient layer 14. The electron holes are widely distributed in a thickness direction from the electron blocking layer 13 side of the composition gradient layer 14, and the entire composition gradient layer 14 has p-type conduction. The electron hole concentration of this p-type region is 1×10¹⁶ cm⁻³ to 1×10²⁰ cm⁻³, and the electron hole concentration decreases with distance from the electron blocking layer 13. The reason why electron holes are reduced in a vicinity of an interface with the p-type contact layer 15 of the composition gradient layer 14 is that the band is bent to match the fermi level at p-type hetero junction.

The maximum Al composition of the first composition gradient layer (Al composition in an interface with the electron blocking layer 13) is preferably lower by 1% to 20% than the Al composition of the electron blocking layer 13. The electron hole concentration can be further increased by polarization due to crystal deformation. The maximum Al composition is, for example, 65% to 95%.

The minimum Al composition of the first composition gradient layer (Al composition in an interface with second composition gradient layer) is preferably lower by 3% to 30% than the maximum Al composition first composition gradient layer. The electron hole concentration can be further increased by polarization due to crystal deformation. In addition, the Al composition preferably has a band energy not absorbing an emission wavelength.

The reduction rate of the Al composition of the first composition gradient layer is preferably 0.1%/nm to 0.3%/nm. Within such a range, the electron hole concentration of the first composition gradient layer can be further increased. The reduction rate of the Al composition may be constant, that is, may vary linearly, or may not be constant.

The first composition gradient layer is undoped. However, the first composition gradient layer may be doped with Mg. The electron hole concentration can be expected to further increase by doping with a p-type impurity. In this case, the Mg concentration is, for example, 1×10²⁰ cm⁻³ or less.

The second composition gradient layer has a Mg concentration higher than the Mg concentration of the first composition gradient layer. Except that, the Al composition of the second composition gradient layer is set same as the first composition gradient layer. That is, the Al composition varies in a thickness direction, and the Al composition is set so as to be reduced with distance from the electron blocking layer 13. By doping the second composition gradient layer with Mg, it can be properly connected with the p-type contact layer 15.

The difference between the maximum Al composition of the second composition gradient layer (Al composition in an interface with the first composition gradient layer) and the minimum Al composition of the first composition gradient layer is 0% to 5%. The maximum Al composition of the second composition gradient layer is preferably same as the minimum Al composition of the first composition gradient layer. That is, the Al composition is preferably continuous from the first composition gradient layer to the second composition gradient layer.

The minimum Al composition of the second composition gradient layer (Al composition in an interface with the p-type contact layer 15) is preferably lower by 3% to 30% than the maximum Al composition of the second composition gradient layer.

The reduction rate of the Al composition of the second composition gradient layer is in the same range of the reduction rate of the Al composition of the first composition gradient layer. The reduction rate of the Al composition of the second composition gradient layer may be same as the reduction rate of the Al composition of the first composition gradient layer.

The Mg concentration of the second composition gradient layer may be any value as long as it is higher than the Mg concentration of the first composition gradient layer. However, the Mg concentration of the second composition gradient layer is preferably 3×10²⁰ cm⁻³ or less to suppress the series resistance.

In the first embodiment, the Al composition of the composition gradient layer 14 is continuously reduced, but may be reduced stepwise. However, the region where the Al composition is constant is preferably as small as possible.

The thickness ratio of the first composition gradient layer to the thickness of the composition gradient layer 14 is preferably 0.4 to 0.7. Within this range, the composition gradient layer 14 can achieve a good contact with the p-type contact layer 15 while the electron hole concentration is sufficiently improved by polarization doping. The thickness ratio is preferably 0.4 to 0.6.

The composition gradient layer 14 may not necessarily have a two-layer structure of the first composition gradient layer and the second composition gradient layer. The composition gradient layer 14 may have only the first composition gradient layer. The composition gradient layer 14 may have three or more layers with different Al composition change rates or Mg concentrations.

The thickness ratio of the composition gradient layer 14 to the total thickness of the electron blocking layer 13, the composition gradient layer 14, and the p-type contact layer 15 is preferably 50% to 90%. Within this range, the composition gradient layer 14 can be sufficiently functioned as the p-type layer.

Instead of the composition gradient layer 14, a layer made of p-type AlGaN doped with Mg may be formed. In this case, the Mg concentration is, for example, 1×10¹⁷ cm⁻³ to 1×10¹⁹ cm⁻³. The Al composition is, for example, 40% to 80%.

The p-type contact layer 15 is disposed on the composition gradient layer 14. The p-type contact layer 15 is made of p-GaN doped with Mg. The p-type contact layer 15 may be made of p-AlGaN having an Al composition lower than the minimum Al composition of the composition gradient layer 14. The Al composition of the p-type contact layer 15 is, for example, 50% or less, preferably 30% or less.

When the p-type contact layer 15 is made of GaN, the thickness is preferably 1 nm to 50 nm. GaN absorbs ultraviolet light emitted from the active layer 12. However, ultraviolet light can be transmitted by sufficiently reducing the thickness. Consequently, a drastic reduction in the external quantum efficiency can be avoided. The thickness of the p-type contact layer 15 is preferably 1 nm to 10 nm. The Mg concentration of the p-type contact layer 15 is, for example, 1×10²⁰ cm⁻³ to 1×10²² cm⁻³.

The p-type contact layer 15 may have a plurality of layers with different Al compositions or Mg concentrations. In the case of multilayer structure, the top layer in contact with the p-side electrode 17 is preferably made of p-GaN or AlGaN having a low Al composition to reduce the contact resistance of the p-side electrode 17. In this case, the Al composition of AlGaN having a low Al composition is 50% or less, preferably 30% or less. The p-type contact layer 15 is made of AlGaN having an Al composition of 50% or less, the thickness of the p-type contact layer 15 is preferably 20 nm or less. Ultraviolet light can be transmitted by sufficiently reducing the thickness.

A hole 23 with a depth reaching the n-type layer 11 is formed in some areas of the surface of the p-type contact layer 15. This hole 23 is provided to expose the n-type layer 11 and form the n-side electrode 16.

As shown in FIG. 2, a plurality of holes 23 is formed in a dot shape. The dots are arranged in an equilateral triangular lattice pattern. However, the hole 23 is not formed in a vicinity of a certain side of the light emitting device 1. This is to leave a region for forming a p-side pad electrode 22 as described later. With such a dot-shaped layout pattern of the holes 23, the surface area of the p-type contact layer 15 is left as large as possible so that the light emitting area is increased without impairing the current diffusivity in the surface.

The planar pattern of the hole 23 is a circle. The planar pattern may be a regular hexagon, a square, an equilateral triangle, or others. For example, the planar pattern may be a regular hexagonal with a m-plane side surface.

In the first embodiment, the holes 23 are arranged in an equilateral triangular lattice pattern. However, the holes 23 may be arranged in a square lattice pattern or a honeycomb pattern.

A diameter of the hole 23 and a distance between centers of adjacent holes 23 are preferably within the following range. This can increase the light emitting area and improve the current diffusivity in the surface. The diameter of the hole 23 is preferably 30 μm to 60 μm. The distance between the centers of the adjacent holes 23 is preferably 100 μm to 250 μm.

The n-side electrode 16 is formed on and in contact with the n-type layer 11 exposed in the bottom of the hole 23. The material of the n-side electrode 16 is, for example, Ti/Al, V/Al. With a planar pattern of a plurality of n-side electrodes 16 each having a dot shape arranged as shown in FIG. 2, the current is diffused in the surface while suppressing the reduction of the light emitting area.

The p-side electrode 17 is formed on and in contact with the p-type contact layer 15, and is disposed on the entire surface other than the end portions. The material of the p-side electrode 17 is Ru, Rh, or an alloy containing those metals as a main component. These materials can achieve a good contact with the p-type contact layer 15. The p-side electrode 17 may include a plurality of layers. In that case, a layer in contact with the p-type contact layer 15 may be made of Ru, Rh, or an alloy containing those metals as a main component. For example, a transparent electrode layer made of ITO or IZO may be deposited on the Ru layer or Rh layer.

The thickness of the p-side electrode 17 is set so as to transmit ultraviolet light with an emission wavelength. The p-side electrode 17 is made of Ru, Rh, or an alloy containing those metals as a main component. Therefore, the reflectance of deep ultraviolet light is comparatively high. However, it was insufficient to further improve the light extraction efficiency of the light emitting device 1. By providing a DBR layer 19 and reducing the thickness of the p-side electrode 17, ultraviolet light emitted from the active layer 12 is transmitted through the p-side electrode 17. Thus, the ultraviolet light can be efficiently reflected by the DBR layer 19.

The thickness of the p-side electrode 17 is preferably 1 nm to 50 nm. Within this range, the ultraviolet light transmitted through the p-side electrode 17 can be efficiently reflected by the DBR layer 19 while maintaining a good contact with p-type contact layer 15. The thickness of the p-side electrode 17 is more preferably 1 nm to 30 nm, and further preferably 1 nm to 20 nm.

As described later, in the first embodiment, the DBR layer 19 is provided instead of the conventional Al layer on the p-side electrode 17. The DBR layer 19 has a UVC reflectance higher than the UVC reflectance of the Al layer, and thus can reflect the ultraviolet light transmitted through the p-side electrode 17.

When the Al layer is formed instead of the DBR layer 19, the p-type contact layer 15 may be exposed in some regions by reducing the thickness of the p-side electrode 17. There was a possibility that the Al layer is in contact with the p-type contact layer 15 so that the contact resistance may be deteriorated. However, in the first embodiment, the DBR layer 19 is formed instead of the Al layer and the DBR layer 19 is an insulator. Even if the p-side electrode 17 is thin and the DBR layer 19 is in contact with the p-type contact layer 15, the contact resistance is not deteriorated and the p-side electrode 17 can maintain a good contact with the p-type contact layer 15.

The etching stop layer 18 is formed on the n-side electrode 16 and in a predetermined region on the p-side electrode 17. Hereinafter, of the etching stop layers 18, a layer on the n-side electrode 16 is referred to as an etching stop layer 18A, and a layer on the p-side electrode 17 is referred to as an etching stop layer 18B. The etching stop layer 18 functions as a stopper when holes 24 and 25 to be described later are formed in the DBR layer 19 and the protective layer 20.

The etching stop layer 18A is entirely formed except for a vicinity of the end portion of the n-side electrode 16. Therefore, the pattern of the etching stop layer 18A is the same as the pattern of the n-side electrode 16.

The etching stop layer 18B has a dot shape, and may be a combination of a dot shape and an elongated shape (wiring shape). This etching stop layer 18B is formed according to the position of the hole 25 to be described later. In a plan view, the hole 25 is set so as to be disposed inside the outer peripheral circle of the etching stop layer 18B.

As described above, the etching stop layer 18B is formed only in a predetermined region on the p-side electrode 17. The reason is the following. If the etching stop layer 18B is formed on the entire surface of the p-side electrode 17, most of the ultraviolet light transmitted through the p-side electrode 17 enters the etching stop layer 18, and a part of the ultraviolet light is absorbed by the etching stop layer 18B. Even if the DBR layer 19 is provided, the reflectance cannot be sufficiently improved. Therefore, the etching stop layer 18B is formed only in the region for forming the hole 25, thereby suppressing the absorption of the ultraviolet light by the etching stop layer 18B.

The material of the etching stop layer 18 is a conductive material resistant to dry etching of the DBR layer 19 and the protective layer 20, for example, a conductive material resistant to dry etching with a fluorine gas. Specifically, the material is Ti, TiN, Ni, Pt, Al, or others, or may be a multilayer film containing these materials.

When the etching stop layer 18B is a multilayer film, a first layer in contact with the p-side electrode 17 is preferably an Al layer or a metal layer containing Al as a main component. The first layer can reflect the ultraviolet light transmitted through the p-side electrode 17 and entered the etching stop layer 18B, thereby further improving the light extraction efficiency. In this case, the thickness of the Al layer is preferably 10 nm to 500 nm, more preferably 80 nm to 200 nm. In the case of a multilayer film, for example, Al/Ti/Ni/Ti/Al or Al/Ti/Pt/Ti/Al may be used.

The entire area of the etching stop layer 18B is preferably 60% or less of the area of the p-side electrode 17. This is to further improve the light extraction efficiency by minimizing the area of the etching stop layer 18B absorbing ultraviolet light with an emission wavelength and making the contact area between the p-side electrode 17 and the DBR layer 19 as large as possible. The area of the etching stop layer 18B is more preferably 50% or less, further preferably, 25% or less. The entire area of the etching stop layer 18B is preferably 3% or more of the area of the p-side electrode 17. This means that the area of the etching stop layer 18B is larger than the area when the etching stop layer is disposed only just below the hole 25 connecting the p-side electrode 17 and the p-side pad electrode 22.

The diameter of the dot of the etching stop layer 18B is set according to the diameter of the hole 25. The diameter of the dot of the etching stop layer 18B is preferably, for example, 1.2 times or more than the diameter of the hole 25. In this case, even if the position of the hole 25 is dislocated or a diameter error occurs, the hole 25 can be adjusted to be disposed inside the outer peripheral circle of the etching stop layer 18B in a plan view so that the function of the etching stop layer 18B is not impaired. The diameter of the dot of the etching stop layer 18B is preferably, for example, 1.5 times or less than the diameter of the hole 25. In this case, the absorption of ultraviolet light by the etching stop layer 18B can be sufficiently reduced. A distance between the dots of the etching stop layers 18B is preferably 1 to 6 times the diameter of the hole 25.

The DBR layer 19 is formed so as to cover the p-side electrode 17, the etching stop layer 18, the hole 23, the side surface of the semiconductor layers exposed on the outer peripheral side surface of the light emitting device (a deposited structure from the n-type layer 11 to the p-type contact layer 15). The DBR layer 19 is in contact with a region except for the etching stop layer 18B formed on the p-side electrode 17. The DBR layer 19 is a layer provided to reflect ultraviolet light transmitted through the p-side electrode 17. Moreover, the DBR layer 19 is also a layer reflecting ultraviolet light traveling toward the outer peripheral part of the light emitting device or the hole 23.

When the Al layer is formed instead of the DBR layer 19, the Al layer cannot cover the side surface of the semiconductor layers (the outer peripheral side surface of the light emitting device or the side surface of the hole 23) because it is an electrical conductor. However, the DBR layer 19 can cover the outer peripheral side surface of the light emitting device, or the side surface and the bottom surface of the hole 23 because it is an insulator. Therefore, the area reflecting ultraviolet light is larger than when the Al layer is used, thereby improving the light extraction efficiency.

The DBR layer 19 has a structure formed by alternately and repeatedly depositing a low refractive index layer and a high refractive index layer with a refractive index higher than the refractive index of the low refractive index layer. The thickness of each of the layers is set so that the reflectance of ultraviolet light with an emission wavelength is higher. The layers may be made of an insulating material that transmits ultraviolet light with an emission wavelength. The high refractive index layer may be made of HfO₂, ZrO₂ or other materials, and the low refractive index layer may be made of SiO₂, Al₂O₃, MgF₂ or other materials. Particularly, HfO₂ has high resistance to deep ultraviolet light, and is suitable as the material of DBR layer 19.

In the first embodiment, the area of the etching stop layer 18 on the p-side electrode 17 is small, resulting in a large contact area between the p-side electrode 17 and the DBR layer 19. Thus, most of the ultraviolet light emitted from the active layer 12 to the p-side electrode 17 side and transmitted through the p-side electrode 17 can enter the DBR layer 19 and be reflected to the substrate 10 side by the DBR layer 19. That is, a decrease in the light extraction efficiency can be suppressed by forming the etching stop layer 18.

The material, thickness, and number of layers of the DBR layer 19 is preferably set so that the reflectance of the DBR layer 19 is 95% or more. Here, the reflectance is the reflectance when ultraviolet light with an emission wavelength entered perpendicular to the main surface of the DBR layer 19. The reflectance is more preferably 97% or more, and further preferably 99% or more.

The incident angle dependence of the reflectance of the DBR layer 19 is preferably set so that the reflectance is 90% or more at any incident angle within a range of −60° to 60°. The incident angle dependence of the reflectance of the DBR layer 19 can be set according to the refractive index, thickness, and number of layers of the DBR layer 19.

The protective layer 20 is formed so as to cover the DBR layer 19. The material of the protective layer 20 is, for example, SiO₂. In a predetermined region of the protective layer 20 and the DBR layer 19, a plurality of holes 24 and 25 passing through the protective layer 20 and the DBR layer 19 is formed. The hole 24 is a hole for connecting the etching stop layer 18A and the n-side pad electrode 21. The hole 25 is a hole for connecting the etching stop layer 18B and the p-side pad electrode 22.

The hole 24 is formed in a region corresponding to the top of the etching stop layer 18A. Therefore, the layout pattern of the hole 24 is the same as the layout pattern of the etching stop layer 18A. The hole 24 is also formed so as to be inside the outer peripheral circle of the etching stop layer 18A in a plan view. For example, the diameter of the hole 24 is 0.5 to 0.9 times the diameter of the etching stop layer 18A. The planar pattern of the hole 24 is a circle same as the planar pattern of the etching stop layer 18A. The planar pattern of the hole 24 may be a regular hexagon, a square, or an equilateral triangle.

The hole 25 is formed in a region corresponding to the top of the etching stop layer 18B. The hole 25 has a dot shape, and the planar pattern of the hole 25 is a circle. As shown in FIG. 2, in a vicinity of on the side with no hole 23 formed of the light emitting device 1, a plurality of holes 25 is formed along that side. The hole 25 is formed so as to be inside the outer peripheral circle of the etching stop layer 18B in a plan view.

The diameter of the hole 25 is preferably 60 μm or less. By reducing the diameter of the hole 25, the diameter of the etching stop layer 18B can also be reduced. Thereby, the light extraction efficiency can be improved. The diameter of the hole 25 is more preferably 50 μm or less, further preferably 40 μm or less. The diameter of the hole 25 is preferably 10 μm or more to achieve a good conduction between the p-side electrode 17 and the p-side pad electrode 22. The diameter of the hole 25 is more preferably 20 μm or more.

A distance between the centers of the adjacent holes 25 is preferably 50 μm to 250 μm. Within this range, current diffusivity and light extraction efficiency can be both sufficiently improved. Each dot of the etching stop layer 18B is formed to each of the holes 25. Therefore, a distance between the centers of the adjacent dots of the etching stop layer 18B is also preferably within the same range of the distance between the centers of the adjacent holes 25.

The planar pattern of the hole 25 is not necessarily a circle, but may be an equilateral triangle, a square or a regular hexagon.

The number of dots of the hole 25 or the etching stop layer 18B may be one or more than one. However, to diffuse current in the surface, a plurality of holes 25 or etching stop layers 18B is preferably formed as a dot as in the first embodiment. In that case, they may be arranged in a straight line as in the first embodiment, but may be arranged in a two-dimensional layout. For example, they may be arranged in an equilateral triangle lattice, a square lattice, or a honeycomb shape. To improve the current diffusion into the surface, a dot shape and an elongated shape may be combined. For example, a wiring elongating in a direction opposite to the side with no hole 23 may be connected to the dots arranged.

A reflective layer made of Al, Mg, or an alloy containing those metals as a main component may be formed in contact with the DBR layer 19 between the DBR layer 19 and the protective layer 20. However, no reflective layer is provided in the region for forming the holes 24 and 25. The DBR layer 19 has an incident angle dependence of reflectance. In some cases, ultraviolet light entering the DBR layer 19 at a large incident angle cannot be sufficiently reflected. For example, when a number of deposition layers of the DBR layer 19 is reduced, the incident angle dependence is remarkable. On the other hand, the reflective layer is made of metal, and has a low incident angle dependence. By providing a reflective layer on and in contact with the DBR layer 19, ultraviolet light with a large incident angle can be reflected, and the reflective layer can compensate for the low reflectance of the DBR layer 19 at large incident angles. The thickness of the reflective layer is, for example, 30 nm to 200 nm. Within in this range, the reflectance can be sufficiently increased.

The n-side pad electrode 21 is formed on the protective layer 20 and in a region corresponding to the top of each of the holes 24. The etching stop layer 18A and the n-side pad electrode 21 are connected through the holes 24. Thus, the n-side pad electrode 21 and the n-side electrode 16 are electrically connected.

The p-side pad electrode 22 is formed on the protective layer 20 and in a region corresponding to the top of each of the holes 25. The etching stop layer 18B and the p-side pad electrode 22 are connected through the holes 25. Thus, the p-side pad electrode 22 and the p-side electrode 17 are electrically connected. In this way, by connecting the p-side pad electrode 22 and the p-side electrode 17 in dots through the holes 25, a contact area between the p-side electrode 17 and the DBR layer 19 can be enlarged, thereby increasing the area for reflecting ultraviolet light.

In the light emitting device 1 according to the first embodiment, the etching stop layer 18B is formed in a dot shape, and a contact area between the p-side electrode 17 and the DBR layer 19 is larger. Therefore, ultraviolet light transmitted through the p-side electrode 17 can be efficiently reflected by the DBR layer 19. As a result, the light extraction efficiency of the light emitting device 1 can be improved.

### 2. Method for Manufacturing Light Emitting Device

Next will be described a method for manufacturing the light emitting device 1 according to the first embodiment with reference to the drawings.

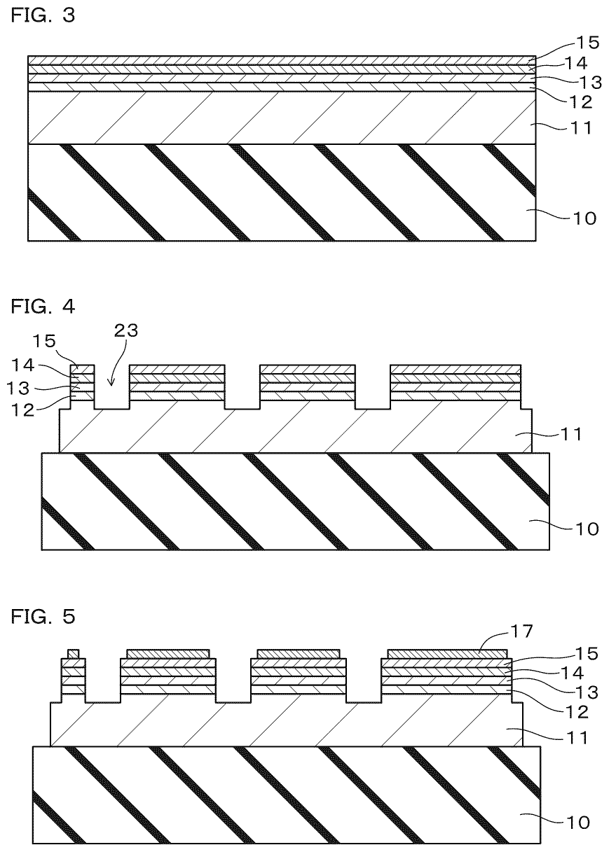

Firstly, an n-type layer 11, an active layer 12, an electron blocking layer 13, a composition gradient layer 14, and a p-type contact layer 15 are sequentially deposited through a buffer layer on a substrate 10 through metal organic chemical vapor deposition (refer to FIG. 3).

Subsequently, a predetermined region of the p-type contact layer 15 is removed by dry etching until reaching the n-type layer 11 to form a hole 23 (refer to FIG. 4).

Next, a p-side electrode 17 is formed on the p-type contact layer 15 through sputtering or deposition (refer to FIG. 5).

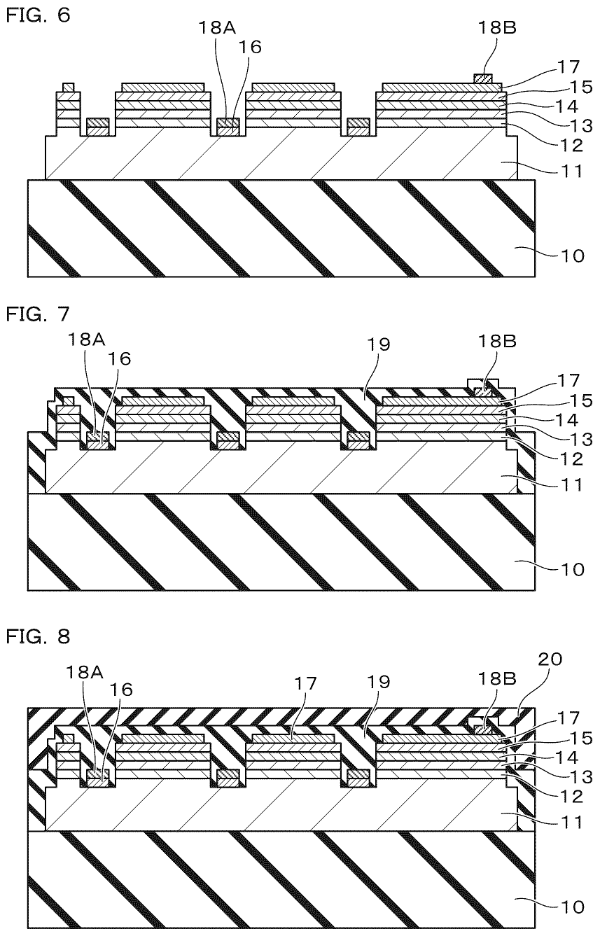

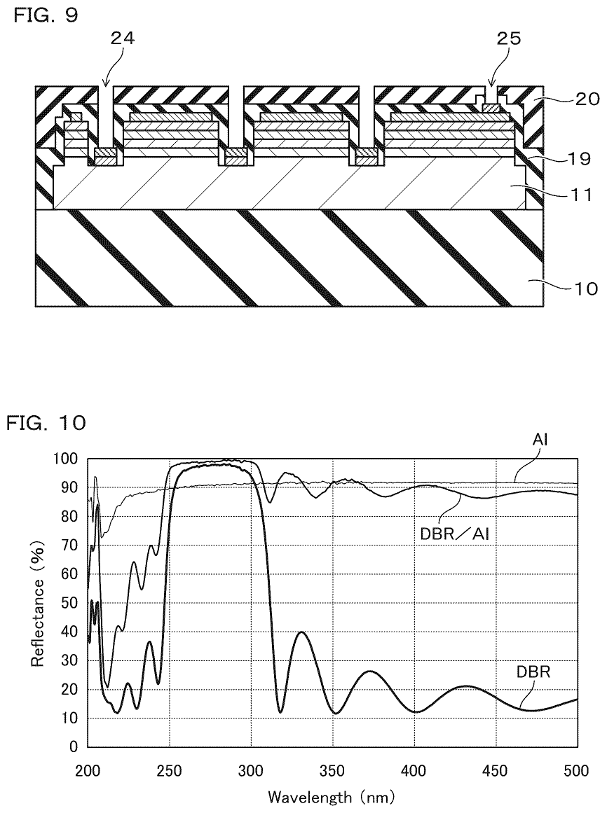

An n-side electrode 16 is formed on the n-type layer 11 exposed in the bottom of the hole 23 through sputtering or deposition. Then, heat treatment is performed to reduce the contact resistance of the n-side electrode 16, and activate the p-type impurity. Subsequently, etching stop layers 18A and 18B are formed in a predetermined region on the n-side electrode 16 and the p-side electrode 17 (refer to FIG. 6).

A DBR layer 19 is formed so as to cover the p-side electrode 17, the etching stop layers 18A and 18B, the holes 23, and the outer peripheral side surface of the light emitting device (refer to FIG. 7). The DBR layer 19 is formed through a method such as sputtering, deposition, and atomic layer deposition.

A protective layer 20 is formed so as to cover the DBR layer 19 through a method such as chemical vapor deposition, sputtering, and deposition (refer to FIG. 8).

Subsequently, holes 24 and 25 passing through the protective layer 20 and the DBR layer 19 are formed by dry etching. Here, the formation of the holes 24 and 25 is stopped when the etching stop layers 18A and 18B are exposed because the etching stop layers 18A and 18B have been formed. Thus, the holes 24 and 25 can be accurately formed.

An n-side pad electrode 21 and a p-side pad electrode 22 are formed in a predetermined region on the protective layer 20. Thus, the etching stop layer 18 on the n-side electrode 16 is connected with the n-side pad electrode 21 through the hole 24, and the etching stop layer 18 on the p-side electrode 17 is connected with the p-side pad electrode 22 through the hole 25. From the above, the light emitting device 1 according to the first embodiment as shown in FIG. 1 is manufactured.

### 3. Experimental Examples of First Embodiment

DBR set so as to have a high reflectance to deep ultraviolet light, was prepared, and the wavelength dependence of the reflectance of DBR was measured. The wavelength dependence of the reflectance was also measured in the same way when Al was formed in contact with DBR. For comparison, the wavelength dependence of the reflectance of Al was also measured. FIG. 10 is a graph showing the wavelength dependence of the reflectance of DBR, DBR/Al, and Al. DBR was formed by alternately depositing HfO₂ and SiO₂, and had a thickness and a number of pairs simulated so that the reflectance is 97% or more within a wavelength range of 270 nm to 280 nm. The thickness of the Al was 1000 nm. The reflectance was measured for the light incident at an incident angle of 10° to the main surfaces of DBR and Al.

As shown in FIG. 10, it was found that in the UVC band with a wavelength of 280 nm or less, the reflectance of DBR or DBR/Al can be increased higher than the reflectance of Al. It was also found that in the case of DBR/Al, the reflectance can be further improved than in the case of DBR only. At the wavelength of 280 nm, the reflectance of DBR was 98.1% and the reflectance of DBR/Al was about 99.3% while the reflectance of Al was 91.3%. These results indicate that Ru/DBR or Rh/DBR structure can improve the reflectance than Ru/Al or Rh/Al structure.

### 4. Variations of First Embodiment

A wiring patterned intermediate electrode may be formed through an insulating film between an n-side pad electrode 21 and an etching stop layer 18A, and between a p-side pad electrode 22 and an etching stop layer 18B. Each of the etching stop layers 18A and the n-side pad electrode 21, and each of the etching stop layers 18B and the p-side pad electrode 22 may be connected by this intermediate electrode.

In the first embodiment, the dots of the n-side electrodes 16 could not be arranged on the entire surface to leave an area for forming the p-side pad electrode 22. However, by providing the intermediate electrode, the dots of the n-side electrodes 16 can be arranged in any layout. The dots of the n-side electrodes 16 can be arranged on the entire surface. As a result, the surface uniformity of light emission can be improved and the light emitting area can be increased. By providing the intermediate electrode, the planar patterns of the n-side pad electrode 21 and the p-side pad electrode 22 can be freely set.

1. A flip-chip type ultraviolet light emitting device comprising:
an n-type layer made of n-type group III nitride semiconductor;
an active layer formed on the n-type layer and made of group III nitride semiconductor,
a p-type layer formed on the active layer and made of p-type group III nitride semiconductor;
a p-side electrode formed on the p-type layer, including a layer made of Ru, Rh, or an alloy containing those metals as a main component and formed in contact with the p-type layer, and having a thickness that transmits ultraviolet light with an emission wavelength;
an insulating DBR layer formed on and in contact with a part of the p-side electrode, and reflecting ultraviolet light with an emission wavelength; and
a second p-side electrode being electrically connected with the p-side electrode through a hole formed in a region on the p-side electrode of the DBR layer.

2. The light emitting device according to claim 1, wherein the DBR layer is formed on and in contact with a part of the p-side electrode, and in contact with at least one side of the n-type layer, the active layer, and the p-type layer.

3. The light emitting device according to claim 1, wherein the emission wavelength is 200 nm to 280 nm.

4. The light emitting device according to claim 1, wherein the DBR layer contains HfO₂.

5. The light emitting device according to claim 1, wherein the thickness of the p-side electrode is 1 nm to 50 nm.

6. The light emitting device according to claim 1, wherein
the p-type layer includes a p-type contact layer in contact with the p-side electrode and made of GaN, and
the thickness of the p-type contact layer is 1 nm to 50 nm.

7. The light emitting device according to claim 1, wherein
the p-type layer includes a p-type contact layer in contact with the p-side electrode and made of AlGaN having an Al composition of 50% or less, and
the thickness of the p-type contact layer is 20 nm or less.

8. A method for manufacturing a flip-chip type ultraviolet light emitting device, the method comprising:
forming an n-type layer made of n-type group III nitride semiconductor;
forming an active layer made of group III nitride semiconductor on the n-type layer;
forming a p-type layer made of p-type group III nitride semiconductor on the active layer;
forming a p-side electrode on the p-type layer, the p-side electrode including a layer made of Ru, Rh, or an alloy containing those metals as a main component and formed in contact with the p-type layer, and having a thickness that transmits ultraviolet light with an emission wavelength;
forming an insulating DBR layer on and in contact with a part of the p-side electrode, the DBR layer reflecting ultraviolet light with an emission wavelength; and
forming a second p-side electrode to be electrically connected with the p-side electrode through a hole formed in a region on the p-side electrode of the DBR layer.
